(19) United States
(12) Patent Application Publication
(10) Pub. No.: US 2009/0297709 A1
(43) Pub. Date: Dec. 3, 2009

(54) CARBON ENCAPSULATED METAL PARTICLES AND METHOD OF MANUFACTURING THE SAME

(75) Inventors: ALEXANDRE YOURI ZAITSEV, MISSISSAUGA (CA); FRANCISCO ROBINSON, MISSISSAUGA (CA); NAM HOAI NGUYEN, MILTON (CA); VLADMIR PASERIN, MISSISSAUGA (CA); CUONG VAN LUONG, MISSISSAUGA (CA)

Correspondence Address: VALE INCO INTELLECTUAL PROPERTY GROUP, PARK 80 WEST - PLAZA TWO, SADDLE BROOK, NJ, 07663, US

(73) Assignee: VALE INCO LIMITED, Toronto (CA)

(21) Appl. No.: 12/128,735

(22) Filed: May 29, 2008

(51) Int. Cl. C23C 16/16; B32B 5/16

(52) U.S. Cl. 427/255.28; 428/403

(57) ABSTRACT

A method of manufacturing commercial grade, carbon-coated or core-shell type metal powders with highly thermostable characteristics utilizes high-temperature carbonyl decomposition in the presence of carbon monoxide under normal atmospheric conditions.

### TECHNICAL FIELD

The present invention relates generally to the field of carbon encapsulated particles and in general to a process of high temperature carbonyl decomposition in the presence of carbon monoxide to produce commercial grade, carbon-coated metal powders with highly thermostable characteristics in particular.

### BACKGROUND OF THE INVENTION

Transition metals, such as nickel, are used in a broad range of manufacturing processes. They are credited with improvement of mechanical properties and corrosion resistance of alloy steels, enhancement of conductivity and magnetic properties of electronic materials, and a variety of catalytic uses. Many of these applications rely on high purity, finely divided forms of transition metals and other special morphologies being adapted to meet specific materials needs, for which a versatile and economic production technology is needed. The nickel carbonyl process is one process well suited to meet these needs.

The nickel carbonyl process, originally discovered and developed by Ludwig Mond at the end of the 19th century, is used as a method of refining impure nickel. Nickel reacts selectively with carbon monoxide to form nickel carbonyl gas, Ni(CO)₄, which can be thermally decomposed back to nickel metal at moderate temperatures with a fill recovery of carbon monoxide:

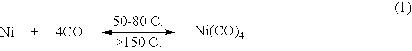

These reactions form the basis of closed-loop operation of a modern carbonyl refinery. The process also allows uniform nickel deposition on porous, three-dimensional substrates and carbon.

Nickel powders can be made by a number of different processes, including atomization from melts or precipitation from solutions. However, atomization processes tend to give relatively large particles, while precipitation processes tend to introduce impurities. Both processes can be difficult to control economically at fine particle sizes. The nickel carbonyl chemical vapor deposition (CVD—also known as “thermal shock decomposition”) process, on the other hand can be tuned to produce much finer particles of higher purity. With sufficient production know-how incorporating modern equipment and controls, the particle shape, size and surface morphology can be accurately controlled.

CVD may be defined as the deposition of a solid on a heated surface from a chemical reaction in the vapor phase. It belongs to the atomistic class of vapor transfer processes. The process requires chemical precursors with high vapor pressure. CVD has several advantages to other vapor transfer processes including: relatively simple equipment that does not require ultra-high vacuum and is adaptable to many process variations.

The chemical reactions used in CVD include thermal decomposition (pyrolysis), reduction, hydrolysis, disproportionation, oxidation, carburization and nitridization initiated by thermal, plasma or photo enhanced activation. The general details of the thermodynamics, kinetics and chemistry of CVD are well known.

Thermal CVD is characterized by the need for temperature that is material dependent generated by resistance heating, high frequency induction, radiant heating, hot plate heating or a combination. Reactors can be horizontal or vertical. Pressure ranges from above atmospheric to a few mTorr.

Hot wall thermal CVD reactors are isothermal furnaces generally heated by resistance elements. They have the advantage of being able to give very precise temperature control to their operators.

Ni powders produced by the carbonyl process have been available in the metal powders market since the 1940's. They can be grouped into three major categories: filamentary powders, discrete, quasi-spherical powders of highly textured, spiky surface morphology and discrete, quasi-spherical powders with smoother surface morphology.

The commercial powder decomposers are large-scale CVD reactors (vertical, electrically heated hot wall cylinders) schematically shown in FIG. 1. The feed gas, containing the carbonyl precursor and special gas additives, enters the reactor at the top of the vessel and decomposes in the free space of the reactor volume. The resulting high-purity nickel particles are collected in the product collection system at the bottom of the reactor. The reactor typically has a length to diameter ratio of about 5:1 and is heated by conduction through the walls. (The heating of the gas itself is both by conduction and radiation) The metal carbonyl decomposes in the inner space of the reactor chamber and the resultant aerosol is carried down, through the lumen of the apparatus into a powder consolidator. In some configurations, the feeding of gas from the top of the reactor means that the settling of particles that are formed from the reaction process into the consolidator is gravity assisted. The process is highly efficient and environmentally friendly since all reaction by-products are recycled in a closed loop refinery circuit. Representative processes may be found in U.S. Pat. No. 1,836,732 to Schlecht et al.; U.S. Pat. No. 2,663,630 to Schlect al. and U.S. Pat. No. 2,851,347 to Schlect et al. Vertical decomposers are disclosed.

In a spray pyrolysis CVD process the precursors used in these reactions may be a mist of a solution containing a dissolved metal or metal compound that decomposes under high temperature to yield metal particles and typically utilizes aerosol hot-wall tubular reactors.

The morphology of these metal powders may be controlled with the use of additives introduced into the carbonyl process. U.S. Pat. No. 3,367,768 to West et al. discloses the addition of ammonia to a decomposer. U.S. Pat. No. 3,702,761 to Llewelyn introduces forms of nitrogen oxide to expedite the process. U.S. Pat. No. 4,673,430 to Pfeil teaches the utility of adding sulfur and sulfur containing compounds to produce fine spherical nickel powders.

The formation of carbon by disproportionation of CO (the Boudouard reaction—formula 2 below) in the carbonyl process provides the possibility to control the nickel particle carbon content.

2CO [symbol] C+CO₂ (2)

By carefully controlling the homogeneous carbonyl decomposition conditions, similar powder morphologies inherent to commercially available powders can be obtained with primary particles reaching micron, sub-micron and nanometer dimensions. These highly spherical, smooth Ni powders are designed to meet the needs of the electronics industry. In particular, this powder is suitable for the production of thin layer, base metal electrode for multi-layer ceramic capacitors (MLCC's).

In order to attain the very narrow size distributions suitable for MLCC's and other applications it is important to design the reactor so that the flow field of the processing gas has a velocity profile closer to the ideal plug-flow form, in which all parcels or flux of the fluid are traveling within the reactor at the same velocity. Unless the flow is perfectly uniform, particles produced in different parts of the reactor will be made under different conditions of temperature, concentration and time. A process of producing metal powders with tight particulate size range tolerances using an upflow reactor using differential pressure is disclosed in assignee's U.S. Pat. No. 7,344,584 B2 to Coley, et al.

In the past, MLCC's were manufactured by laminating a number of thin dielectric layers and a number of inner electrodes made from Ag—Pb alloy. The electronics manufacturing business has more recently tended towards replacing the inner electrode material with nickel, which is less expensive, to lower the cost of the MLCC in the late 1990's. The nickel inner electrode of the MLCC is formed by coating a conductive paste, which comprises nickel metal powder, drying and co-firing the ceramic dielectric layers and the inner electrode layers.

A primary drawback of this method is the issue of differing shrinkage rates of the constituent materials that comprise the MLCC being fired. The shrinkage rate of the inner electrode layer is higher than that of the ceramic dielectric layer and it begins at a lower temperature (about 400-500° C.) compared to the ceramic dielectric layer, which is more than about 1,100° C. (when BaTiO₃ is used). These differences of the shrinkage rate and the temperature of shrinking between the inner electrode layer and the ceramic dielectric layer lead to delamination of the MLCC.

A number of solutions have been developed by the electronics industry to address the problem of shrinkage, including reducing the oxygen content of the nickel powder and using composite nickel powder such as oxide-coated nickel powder. See for example, dry-type mechanochemical mixing using a hybridizer (see the Japanese patent laid-open publication No. 1999-343501); spray pyrolysis (see U.S. Pat. No. 6,007,743 to Asada, et al.); and wet-type sol-gel coating (see U.S. Pat. No. 6,478,882 to Miyazaki, et al.) for techniques proposed to coat nickel powder with oxides.

Mechanochemical mixing of nickel powders and oxides has proven to be ineffective at reducing the heat shrinkage rate, as the materials are prone to density separation (see the Japanese patent laid-open publication No. 1999-343501).

With spray pyrolysis, oxides were formed on both the surface of the nickel particle and within the nickel particle itself resulting in impurities that negatively affect the electrical qualities of the compound (see U.S. Pat. No. 6,007,743).

As most wet-type sol-gel coating methods use a water-based coating solution (see U.S. Pat. No. 6,682,776 to Asaki, et al.), hydroxyl groups remain in the coating layer of the produced nickel powder which causes agglomeration of the oxide-coated nickel powder during the process of drying. The properties of the inner electrode layer printed on the dielectric sheet can be fatally affected by the agglomeration of the nickel powder in the conductive paste.

An alternate method of preparing nickel-particle powder with improved shrinkage property during the firing process was disclosed by U.S. Pat. No. 7,258,721 to Choi, et al. According to the inventors, the method includes taking commercially available nickel powder (manufactured by various methods including vaporization, spray pyroloysis and liquid-phase reduction.), suspending the powder in a polyol dispersion and reducing medium; and heating the solution to decompose the polyol to carbon which is absorbed or incorporated into the nickel metal particle. To avoid deterioration of the reacting materials the heating process is regulated to be below 350° C. Choi et al. go on to further describe the conductive paste for manufacturing MLCC's comprising the carbon-coated nickel-powder described above combined with an organic binder, an organic solvent and certain additives such as plasticizer, anti-thickening agents and dispersants.

A simple synthetic route to prepare carbon-coated nickel nanoparticles using ionic liquid and microwave heating was demonstrated by D. S. Jacob, et al. in their paper entitled “Carbon-Coated Core Shell Structured Copper and Nickel Nanoparticles Synthesized in an Ionic Liquid”, published in The Journal of Physical Chemistry B Letters, vol. 110, N. 36, 2006.

In commercial carbonyl Ni powder, the carbon content varies from ˜0.1 to about 0.6% for different types of powders, depending on the decomposition conditions. The carbon is normally present in the bulk of the particle and on the surface. Transition electron microscope (TEM) studies have shown that the surface carbon of carbonyl Ni powders is of the turbostatic, graphitic type. The images in FIGS. 2 and 3 show a sample of carbon “nanoshells” liberated from nickel powder by leaching in nitric acid. The basal planes of graphite are clearly visible on the surface of the imaged particle in FIG. 3.

Nickel particles containing enhanced surface carbon deposits have been imaged using TEM and elementally mapped using Electron Energy Loss Spectroscopy (EELS). Such a sample containing a total carbon of ˜2%, with most of the carbon deposited at the surface regions. This powder exhibited unique thermal properties such as very low shrinkage (<2%) as measured in a standard thermo-mechanical analysis (TMA) under reducing atmosphere and temperatures in excess of 1000° C.

U.S. Pat. No. 5,965,267 to Nolan, et al. discloses a process for producing encapsulated nanoparticles using catalytic disproportionation of carbon monoxide in the substantial absence of hydrogen, and a catalyst of transition metal selected from Co, Ni, Fe and heated to temperatures from 300 to 1000° C. A key requirement of the process is the use of a thoroughly dried catalyst, using heated inert gas and hydrogen reduction, with a subsequent hydrogen purge. Nolan et al. further teach the control of the rate of the disproportionation reaction by adjusting CO/CO2 ratios to provide a carbon activity appropriate for the desired product (e.g. 1:5 at 500° C.).

While primarily concerning a process for gas-phase nucleation and growth of single-wall carbon nanotubes from high pressure CO, U.S. Pat. No. 6,761,870 to Smalley et al. disclose an example of using a tube reactor to run both Mond and Boudouard reactions producing powdery nickel particles coated with carbon. The process included supplying high pressure (30 atmospheres) CO that has been preheated (to about 1000° C.) and a catalyst precursor gas (e.g., Ni(CO)₄) in CO that is kept below the catalyst precursor decomposition temperature to a mixing zone.

M. Schallehn, et al. have reported on crytsalline alumina particles coated with polyethylene prepared by a two-step chemical vapor synthesis process using a hot-wall reactor to synthesize the nanocrystalline core, and a RF plasma reactor for the subsequent polymer coating (see M. Schallehn et al., “In-Situ Preparation of Polymer-Coated Alumina Nanopowders by Chemical Vapor Synthesis”, Chemical Vapor Deposition, 9, No. 1, pp 40-44, 2003). This process requires two reaction zones: a decomposition zone for powder formation and a polymer deposition zone.

This survey of carbon-coated nickel powder manufacturing techniques makes it clear that a simple process for producing a carbon-coated nickel nanoparticle in situ and concurrent with the nickel powder production in the free space of a standard tube reactor is a commercial need that has, up until now, remained unaddressed.

### SUMMARY OF THE INVENTION

It is an object of the present invention to provide a method for manufacturing commercial grade, carbon-coated metal powders with highly thermostable characteristics utilizing carbonyl decomposition at temperatures above 1000° C. in the presence of carbon monoxide under normal atmospheric conditions.

It is another object of the present invention to provide a process for carbon coating metal powders during the powder manufacturing process.

It is yet another object of the present invention to provide a process for carbonyl decomposition in the volume of a reaction tube at temperatures above 1000° C. at normal atmospheric pressures.

It is a further object of the present invention to provide for the manufacture of conductive electrode forming pastes, conductive polymers, additives, catalysts and nanopowders.

It is a still further object of the present invention to provide for the manufacture of carbon encapsulated metal particles suitable for use in the manufacture of MLCC chips and other applications.

Accordingly, a manufacturing process is disclosed utilizing high temperature carbonyl decomposition in the presence of carbon monoxide to produce commercial grade, carbon-coated metal powders with highly thermostable characteristics.

### BRIEF DESCRIPTION OF THE DRAWINGS

In the drawings:

FIG. 1 is a diagram of a metal carbonyl powder decomposer;

FIG. 2 is an low magnification scanning electron image of carbon nanoshells obtained by nitric acid leaching of Ni powder;

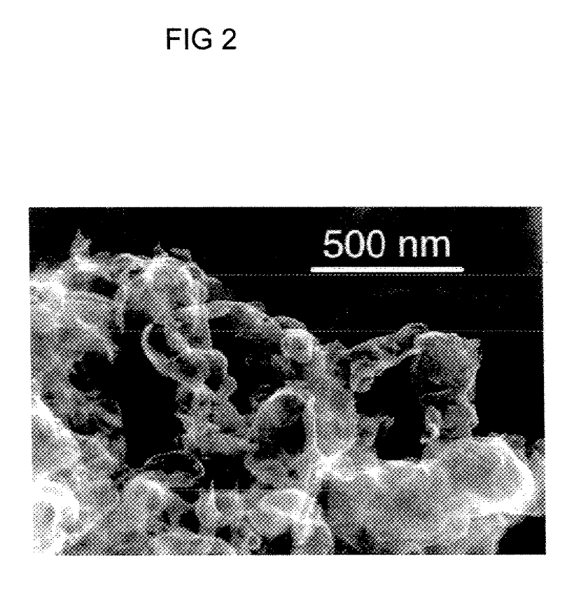

FIG. 3 is a high-resolution transmission electron microscopy (HRTEM) image showing the basal planes of the graphite; the layer found on the surface of a nickel particle;

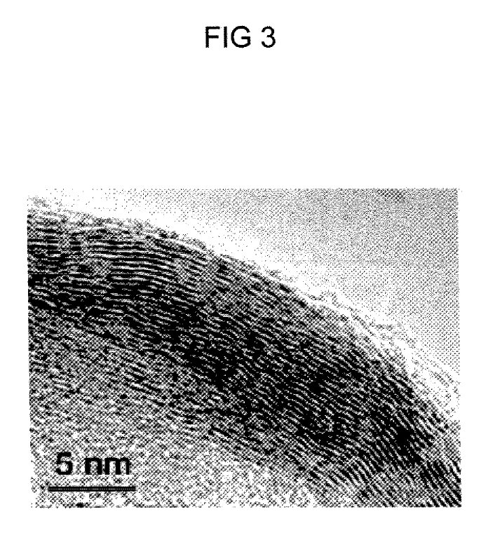

FIG. 4 is a HRTEM image showing carbon encapsulated nickel nanoparticles produced by the manufacturing method according to the present invention;

FIG. 5 is a high-resolution scanning electron microscopy image showing carbon encapsulated nickel nanoparticles produced by the manufacturing method according to the present invention; and

FIG. 6 is a graph of comparative shrinkage rates with respect to temperature of carbon encapsulated versus non-encapsulated nickel powders when fired.

### DESCRIPTION OF THE PREFERRED EMBODIMENTS

The present invention will be described in more detail by describing embodiments thereof.

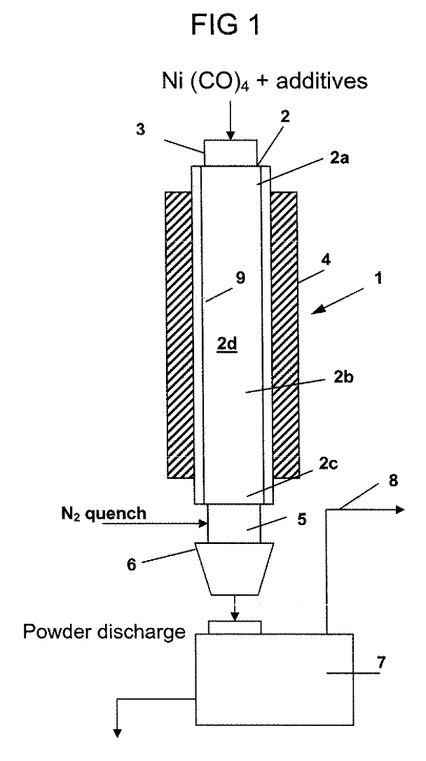

Referring now to the drawings, in which like reference numerals are used to refer to the same or similar elements, FIG. 1 shows an embodiment of the method of manufacturing carbon encapsulated transition metal particles according to the present invention comprising a metal carbonyl vapor decomposer 1 employing an essentially vertically oriented downflow reactor 2 having a vertical axis substantially perpendicular to the horizontal. Metal carbonyl vapors in an inert carrier gas together with additives necessary for the required product morphology flow into an upper portion 2a of the reactor through an inlet 3 situated at the upper end of the reactor 2. The reactor 2 has a first section 2b that is heated by coils 4. The resultant metal particles exit from an outlet 5 at a lower portion 2c of the first section of the reactor, and are quenched by nitrogen at a temperature of about 400 to 800° C. in a second section 6 of the reactor. The powder is then collected in a filter 7 and discharged. The dust-free exit gas is returned to the refinery circuit 8 where it can either be processed and recycled or incinerated. In reactor 2, processing by decomposition of the gaseous precursor substantially occurs in an inner tube 9 in first section 2a surrounded by the heating coils 4. The first section 2a of the reactor that includes the inner tube 9 and the coils 4 is also a middle section 2d of the reactor in FIG. 1, between the upper portion 2a with inlet 3, and the lower portion 2c with outlet 5. Typical controls, safety devices, instrumentation, ports and the like are not shown for the sake of simplicity.

The manufacturing method according to the present invention comprises a preparatory stage whereby streams of gaseous metal carbonyl, CO and CO₂, N₂ and required additives for controlling product morphology are mixed at ambient temperature and atmospheric pressure prior to their introduction into the reactor 2. This gaseous mixture is then introduced simultaneously into the reactor 2 at the inlet 3. The wall temperature at the first 2a or middle section 2d of the reactor 2 (the “hot zone”) is kept at a temperature range from about 1000° C., or not less than about 300° C. below the melting point of the metal, to above the melting point of the metal constituent of the carbonyl vapor. After passing the hot zone, the gas flow is quenched by nitrogen and the powder is collected in the filter 7.

The particle size may be controlled by traditional methods known in the art such as changes in gas velocity, concentration of the precursor and temperature manipulation. In addition, the amount of carbon coating may also be controlled by varying the amount of CO₂ that is introduced into the system. Experiments have shown that the amount of carbon content can be reduced with the addition of CO₂. The results of these experiments are shown in table 1 below.

TABLE 1
% of carbon content at varying Levels of CO₂ concentration

| Operating Temperature: | 1600° C. |
|---|---|
| Total Flow Rate: | 30 l/min. |
| Ni(CO)4 concentration: | 1% |

| CO₂, vol. % | C., % |
|---|---|
| 0 | 2.67 |
| 10 | 0.61 |
| 20 | 0.54 |
| 50 | 0.3 |

The carbon-encapsulated metal particles disclosed in this application may also be manufactured using a vertically oriented upflow reactor as disclosed in assignee's U.S. Pat. No. 7,344,584 B2 to Coley, et al.

Thus, the present invention will be described in more detail with reference to the following examples. The following examples are for illustrative purposes and are not intended to limit the scope of the invention.

### Example 1

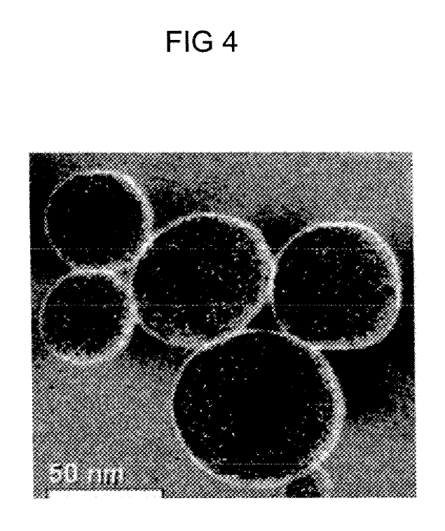

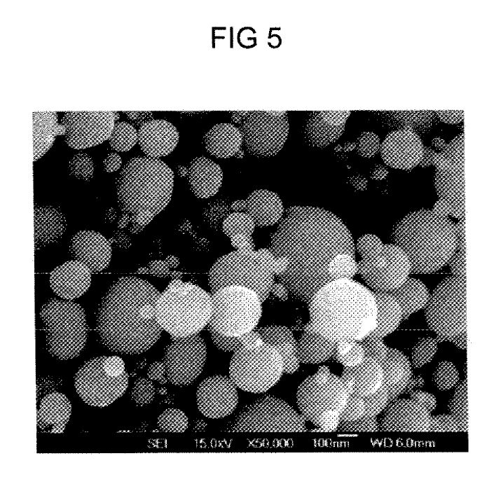

A gaseous precursor mix of 0.8% nickel carbonyl, CO and N₂ at ambient temperature and atmospheric pressure were introduced into the reactor with a flow rate of 20 l/min. The wall temperature of the reactor hot zone was 1500° C. After passing the hot zone, the gas flow was quenched by nitrogen and the powder was collected in a filter bag. The yield of the product was 85%. 15% of the powder was collected from the reactor walls. The product was analyzed by transmission electron microscopy, which showed carbon coating in white color on the surface of each particle (see FIG. 4). A high resolution scanning electron microscope analysis was also performed on the resultant powder product. The scanning electron microscope (SEM) image is shown in FIG. 5.

### Example 2

A gaseous precursor mix of 10% nickel carbonyl, CO and N₂ at ambient temperature and atmospheric pressure was introduced into the reactor with a flow rate of 40 l/min. The wall temperature of the reactor hot zone was 1700° C. After passing the hot zone, the gas flow was quenched by nitrogen and the powder was collected in a filter bag. The yield of the product was 75%.

### Example 3

A gaseous precursor mix of 1% nickel carbonyl, CO, 50% CO₂ and N₂ at ambient temperature and atmospheric pressure were introduced into the reactor with a flow rate of 30 l/min. The wall temperature of the reactor hot zone was 1600° C. After passing the hot zone, the gas flow was quenched by nitrogen and the powder was collected in a filter bag. The yield of the product was 90%. Carbon content was determined to be 0.3% of the total powder product.

### Example 4

A gaseous precursor mix of 10% iron carbonyl, CO and N₂ at ambient temperature and atmospheric pressure were introduced into the reactor with a flow rate of 40 l/min. The wall temperature of the reactor hot zone was 1700° C. After passing the hot zone, the gas flow was quenched by nitrogen and the powder was collected in a filter bag. The yield of the product was 95%.

### Example 5

A gaseous precursor mix of 5% iron carbonyl, CO and N₂ at ambient temperature and atmospheric pressure were introduced into the reactor with a flow rate of 30 l/min. The wall temperature of the reactor hot zone was 1700° C. After passing the hot zone, the gas flow was quenched by nitrogen and the powder was collected in a filter bag. The yield of the product was almost 85%.

### Thermo-Mechanical Analysis

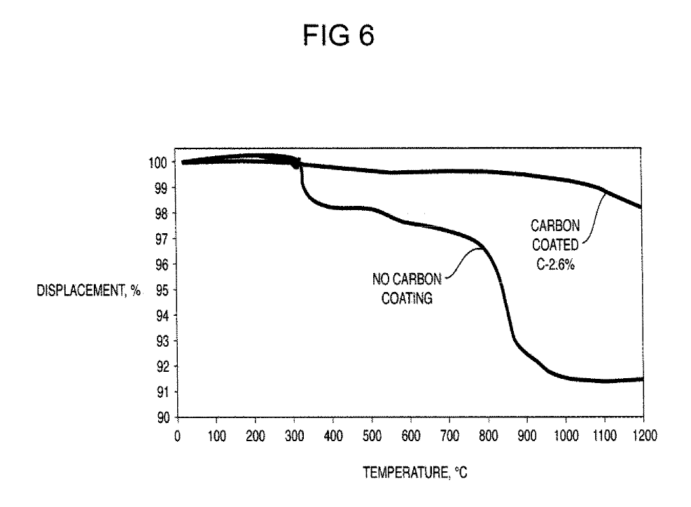

A comparative study of the dynamic shrinkage behavior of the encapsulated nickel nanoparticles manufactured according to the method of the present invention was done using a thermomechanical analyzer (TMA). These measurements were compared with TMA shrinkage measurements made of uncoated nickel powder of the same particle size distribution and morphology. The comparative shrinkage rate plotted against temperature is shown in FIG. 6. The carbon-coated powder was found to have a higher tap density (3.5 g/cm³ for coated vs. 2.25 g/cm³ for uncoated). It also exhibits less than 2% shrinkage at temperatures up to 1200° C. The uncoated nickel powder began exhibiting substantial shrinkage at 300° C.

While a specific embodiment of the invention has been shown and described in detail to illustrate the application of the principles of the invention, it will be understood that the invention may be embodied otherwise without departing from such principles.

What is claimed is:

1. A method for manufacturing metal powders, comprising:
preparing a metal containing process gas;
providing a vertically oriented reactor having an upper and a lower portion;
heating a first section of the reactor to a temperature not less than 1000° C.;
introducing the metal containing processing gas and carbon monoxide gas into the reactor;
initiating the decomposition of the metal containing process gas within the reactor;
causing the metal within the containing process gas to form particles;
allowing the particles to catalyze the formation of carbon layers on the surface of the particles; and
expressing the carbon encapsulated particles from the reactor.

2. The method of claim 1, wherein the metal containing process gas is introduced into the upper portion of the reactor.

3. The method of claim 1, wherein the metal containing process gas is introduced into the lower portion of the reactor.

4. The method of claim 3, including causing the metal containing process gas to assume an upwardly traveling plug-flow velocity profile within the reactor.

5. The method of claim 1, wherein the metal particles are formed by chemical vapor deposition.

6. The method of claim 1, wherein the metal particles are created from the decomposition of metal carbonyl.

7. The method of claim 6, wherein the metal carbonyl is selected from the group consisting of one or more of nickel carbonyl, iron carbonyl, and cobalt carbonyl.

8. The method of claim 1, wherein a dopant selected from the group of one or more of sulfur-containing compound and ammonia is introduced into the reactor.

9. The method of claim 1, wherein a gas selected from the group consisting of one or more of carbon dioxide and hydrogen gas, is introduced into the reactor to control the rate of carbon deposition on the particles.

10. The method of claim 1, wherein the reactor is a tube reactor.

11. The method of claim 1, wherein the first section of the reactor comprises a middle section of the reactor between the upper and lower portions.

12. The method of claim 1, wherein a second section of the reactor is below the first section, the method including quenching the particles with carbon layers thereon in the second section at a temperature between 400 and 800° C.

13. The method of claim 7, wherein the metal process gas her comprises gases selected from the group consisting of one or more of carbon monoxide, nitrogen gas, carbon dioxide and hydrogen gas.

14. The method of claim 1, wherein the wall temperature of the first section is heated to a temperature between 1000 and 1700° C.

15. The method of claim 1, wherein the flow of the metal process gas is quenched by nitrogen.

16. The method of claim 1, wherein the particles are collected by a filter.

17. Carbon encapsulated metal particles manufactured by the method of claim 1.

18. The carbon encapsulated metal particles of claim 19, wherein the metal is selected from the group consisting of one or more of nickel, iron and cobalt.

19. A conductive paste comprising a carbon encapsulated metal particle powder manufactured by the method of claim 1, an organic binder and an organic solvent.

20. The conductive paste of claim 20, comprising a metal selected from the group consisting of one or more of nickel, iron and cobalt.
